(19) United States
(12) Patent Application Publication
(10) Pub. No.: US 2011/0239422 A1
(43) Pub. Date: Oct. 6, 2011

(54) METHOD FOR MANUFACTURING A LIQUID EJECTING HEAD AND METHOD FOR FABRICATING PIEZOELECTRIC ELEMENTS

(75) Inventor: Mitsumi KISHIDA, Shiojiri-shi (JP)

(73) Assignee: SEIKO EPSON CORPORATION, Tokyo (JP)

(21) Appl. No.: 13/070,339

(22) Filed: Mar. 23, 2011

(30) Foreign Application Priority Data
Mar. 30, 2010 (JP) 2010-077505

(51) Int. Cl. H01L 41/22; B41J 2/035

(52) U.S. Cl. 29/25.35; 29/890.1

(57) ABSTRACT

A method for manufacturing a liquid ejecting head, that has piezoelectric elements and offers a good displacement characteristic, including forming a first electrode film on a flow channel substrate; forming a first ferroelectric film on the first electrode film; etching the first ferroelectric film and the first electrode film with a resist film formed on the first ferroelectric film as the mask; removing the resist film by ashing with oxygen plasma; forming a protective resist film so as to cover the central portion of the substrate; removing partly the resist film by ashing with oxygen plasma; removing the resist film and the protective resist film by treatment with an organic remover; forming additional ferroelectric films; forming a second electrode film; and shaping the second electrode film and the ferroelectric films other than the first ferroelectric film into a certain pattern

This application claims a priority to Japanese Patent Application No. 2010-077505 filed on Mar. 30, 2010 which is hereby expressly incorporated by reference herein in its entirety.

### BACKGROUND

1. Technical Field

The present invention relates to a method for manufacturing a liquid ejecting head and a method for fabricating piezoelectric elements. Equipped with piezoelectric elements, the liquid ejecting head can eject droplets through the nozzles thereof.

2. Related Art

The piezoelectric element, which is incorporated in devices such as liquid ejecting heads, is an element obtained by sandwiching a piezoelectric layer with two electrodes. This piezoelectric layer is made of a piezoelectric material or some other kind of ferroelectric material having an electromechanical conversion function. An example of the material used is a crystallized piezoelectric ceramic material.

An example of liquid ejecting heads having piezoelectric elements is ink jet recording heads. In an ink jet recording head, pressure chambers, which communicate with nozzles for ejecting ink droplets, have their own diaphragm as a component. The diaphragm is deformed by the vibration of a piezoelectric element, thereby pressurizing ink contained in the pressure chamber so that ink droplets can be ejected from the nozzle. Two kinds of ink jet recording heads have been commercialized: ones based on longitudinal-vibration piezoelectric actuators that extend and retract along the axial direction of piezoelectric elements, and ones based on flexural-vibration piezoelectric actuators. A typical form of the latter ones can be obtained by forming a uniform piezoelectric film on the whole surface of a diaphragm and then cutting the resultant piezoelectric layer by ion milling or some other appropriate technique into piezoelectric elements for the individual pressure chambers.

An exemplary method for forming a piezoelectric element is as follows. First, a lower electrode film is formed on a substrate. Then, an organic metal compound sol is applied to this lower electrode film, dried, and then defatted into a gel to provide a ferroelectric precursor film. This ferroelectric precursor film is then crystallized by heating at a high temperature to provide the lowermost ferroelectric film (a first ferroelectric film). A resist film is formed on this first ferroelectric film, and then the lower electrode film and the first ferroelectric film are processed together by ion milling with the resist film as the mask. As a result, the lower electrode film and the first ferroelectric film share a certain pattern. Subsequently, the resist film is removed by asking with oxygen plasma or some other appropriate technique. After that, additional ferroelectric films are formed on the first ferroelectric film to provide a piezoelectric layer, and then an upper electrode film is formed on this piezoelectric layer. A resist film is formed on this upper electrode film, and then the piezoelectric layer and the upper electrode film are processed together by ion milling with the resist film as the mask. In this way, a piezoelectric element is completed (see JP-A-2007-152913 and other related publications).

However, there are some problems with this method. In this method, the removal of the first resist film precedes the formation of the second and later ferroelectric films on the first one. As mentioned in JP-A-2007-152913, the first ferroelectric film may be damaged while the first resist film is being removed, and this may result in deteriorated crystallographic properties of the resultant piezoelectric layer, such as orientation disorder. In other words, in this method, the resultant piezoelectric layer may be crystallographically impaired because the second and later ferroelectric films fail to take over crystallographic properties from the first one.

Incidentally, the substrate used for the formation of a piezoelectric element is usually held with a metal ring chuck or some other kind of holding member on its edge. During the ion milling process for the first ferroelectric film (and the lower electrode film), this holding member is heated to a high temperature, and the heat transferred from the holding member may harden the basal resist film in part. To make matters worse, ion milling may etch some portion of the holding member, and the resultant metal contaminants (depositions) may adhere to the basal resist film. The portion of the resist film hardened or contaminated in this way is less removable than the remaining portion.

Admittedly, asking with oxygen plasma or some other similar technique repeated in several rounds can completely remove the resist film even in the case where the film has a hardened or contaminated portion, but this simple approach alone may cause serious damage to the piezoelectric layer.

With any hardened or contaminated portion of the resist film left on the edge of the substrate, however, the film formed on the resist film adheres more weakly to the edge than to the central portion. This may cause some problems during the formation of the second and later ferroelectric films on the first ferroelectric film. For example, the first ferroelectric film and the resist film covering it may detach and produce contaminants, and these contaminants may cause problems such as incomplete etching.

Problems like those mentioned above are not limited to piezoelectric elements for ink jet recording heads and other kinds of liquid ejecting heads; similar problems may be encountered with the fabrication of piezoelectric elements for any kind of apparatus.

### SUMMARY

An advantage of an aspect of the invention is that piezoelectric elements offering a constant and great displacement can be fabricated with improved crystallographic properties of their piezoelectric layer, and another is that liquid ejecting heads having such piezoelectric elements can be manufactured.

To solve the problems mentioned above, an aspect of the invention provides a method for manufacturing a liquid ejecting head. This liquid ejecting head has flow channel substrates and piezoelectric elements. The flow channel substrates each has pressure chambers, which communicate with nozzles for ejecting droplets. On the other hand, the piezoelectric elements are each constituted by a first electrode film, a piezoelectric layer, and a second electrode film. The first electrode film is formed on either one side of each of the flow channel substrates, the piezoelectric layer is a laminate of several ferroelectric films formed on the first electrode film, and the second electrode film is formed on the piezoelectric layer. This method includes the following steps: a step of forming the first electrode film on a flow channel substrate wafer, a wafer having a portion to be divided into several flow channel substrates; a step of forming a first ferroelectric film, or the lowermost one of the several ferroelectric films constituting the piezoelectric layer, by forming a ferroelectric precursor film on the first electrode film to a certain thickness and then degreasing and firing the ferroelectric precursor film; a step of shaping the first ferroelectric film and the first electrode film into a certain pattern by applying a resist to the first ferroelectric film, exposing the resist to light and developing it so that a resist film can be obtained with the pattern, and then etching the first ferroelectric film and the first electrode film with this resist film as the mask; a first resist removal step, more specifically, a step of removing the resist film to some extent in the thickness direction by asking with oxygen plasma; a step of forming a protective resist film to cover the first ferroelectric film by applying a resist to the central portion of the flow channel substrate wafer; a second resist removal step, more specifically, a step of removing the resist film and the protective resist film by treatment with an organic remover with or without any pretreatment; a step of forming the remaining ones of the several ferroelectric films constituting the piezoelectric layer by forming a ferroelectric precursor film on the first ferroelectric film to a certain thickness and then degreasing and firing the ferroelectric precursor film and then repeating the same cycle as many times as needed; and a step of completing the piezoelectric elements by forming the second electrode film on the piezoelectric layer and then shaping the second electrode film and the ferroelectric films other than the first ferroelectric film into a certain pattern.

This method allows removing (peeling off) the resist film from the first ferroelectric film while avoiding damage to the first ferroelectric film. As a result, the other ferroelectric films take over crystallographic properties from the first ferroelectric film, and the resultant piezoelectric layer has excellent crystallographic properties.

The protective resist film preferably covers the whole chip region of the flow channel substrate wafer, or in other words, the entire portion to be divided into the flow channel substrates. This further ensures that the first ferroelectric film can be protected by the protective resist film.

The second resist removal step may further include a step of removing the resist film and the protective resist film by ashing with oxygen plasma. This also contributes to the complete removal of the resist film and the protective resist film.

The first resist removal step may further include a step of removing the portion of the resist film left after ashing with oxygen plasma by treatment with an organic remover. This also contributes to the complete removal of the resist film.

Another aspect of the invention provides a method for fabricating piezoelectric elements. These piezoelectric elements are each constituted by a first electrode film, a piezoelectric layer, and a second electrode film. The first electrode film is formed on each of element substrates, the piezoelectric layer is a laminate of several ferroelectric films formed on the first electrode film, and the second electrode film is formed on the piezoelectric layer. This method includes the following steps: a step of forming the first electrode film on an element substrate wafer, a wafer having a portion to be divided into several element substrates; a step of forming a first ferroelectric film, or the lowermost one of the several ferroelectric films constituting the piezoelectric layer, by forming a ferroelectric precursor film on the first electrode film to a certain thickness and then degreasing and firing the ferroelectric precursor film; a step of shaping the first ferroelectric film and the first electrode film into a certain pattern by applying a resist to the first ferroelectric film, exposing the resist to light and developing it so that a resist film can be obtained with the pattern, and then etching the first ferroelectric film and the first electrode film with this resist film as the mask; a first resist removal step, more specifically, a step of removing the resist film to some extent in the thickness direction by asking with oxygen plasma; a step of forming a protective resist film to cover the first ferroelectric film by applying a resist to the central portion of the flow channel substrate wafer; a second resist removal step, more specifically, a step of removing the resist film and the protective resist film by treatment with an organic remover with or without any pretreatment; a step of forming the remaining ones of the several ferroelectric films constituting the piezoelectric layer by forming a ferroelectric precursor film on the first ferroelectric film to a certain thickness and then degreasing and firing the ferroelectric precursor film and then repeating the same cycle as many times as needed; and a step of completing the piezoelectric elements by forming the second electrode film on the piezoelectric layer and then shaping the second electrode film and the ferroelectric films other than the first ferroelectric film into a certain pattern.

This method also allows removing (peeling off) the resist film from the first ferroelectric film while avoiding damage to the first ferroelectric film. As a result, the other ferroelectric films take over crystallographic properties from the first ferroelectric film, and the resultant piezoelectric layer has excellent crystallographic properties.

### BRIEF DESCRIPTION OF THE DRAWINGS

The invention will be described with reference to the accompanying drawings, wherein like numbers reference like elements.

FIG. 1 is an exploded perspective diagram illustrating a recording head according Embodiment 1.

FIGS. 2A and 2B illustrate a plan view and a cross-sectional view of the same recording head.

FIG. 3 is a cross-sectional diagram illustrating the laminar structure of a piezoelectric element according to Embodiment 1.

FIGS. 4A to 4D are cross-sectional diagrams illustrating a method for manufacturing an ink jet recording head according to Embodiment 1.

FIG. 5 is a cross-sectional diagram further illustrating the method for manufacturing an ink jet recording head according to Embodiment 1.

FIGS. 6A to 6F are cross-sectional diagrams further illustrating the method for manufacturing an ink jet recording head according to Embodiment 1.

FIGS. 7A and 7B are cross-sectional diagrams further illustrating the method for manufacturing an ink jet recording head according to Embodiment 1.

FIGS. 8A to 8C are cross-sectional diagrams further illustrating the method for manufacturing an ink jet recording head according to Embodiment 1.

FIGS. 9A to 9C are cross-sectional diagrams further illustrating the method for manufacturing an ink jet recording head according to Embodiment 1.

FIGS. 10A to 10F are cross-sectional diagrams illustrating a method for manufacturing an ink jet recording head according to Embodiment 2.

FIGS. 11A to 11F are cross-sectional diagrams illustrating a method for manufacturing an ink jet recording head according to Embodiment 3.

### DESCRIPTION OF EXEMPLARY EMBODIMENTS

The following describes an aspect of the invention in detail with reference to embodiments.

### Embodiment 1

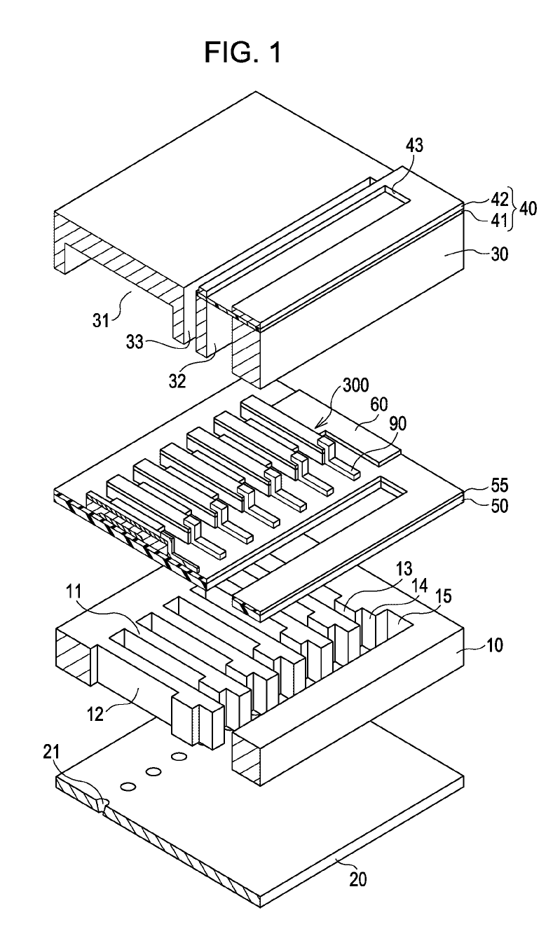

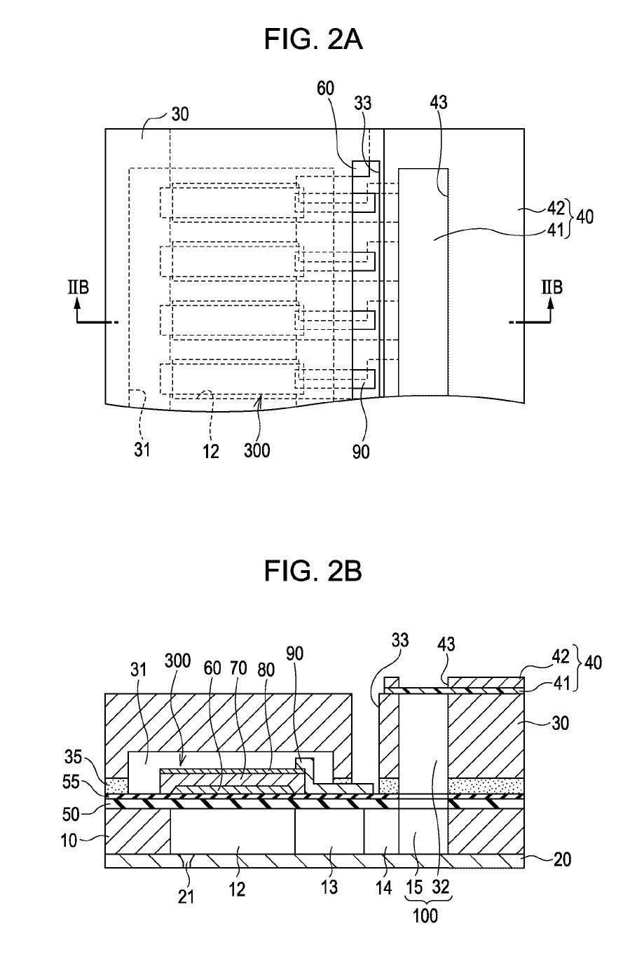

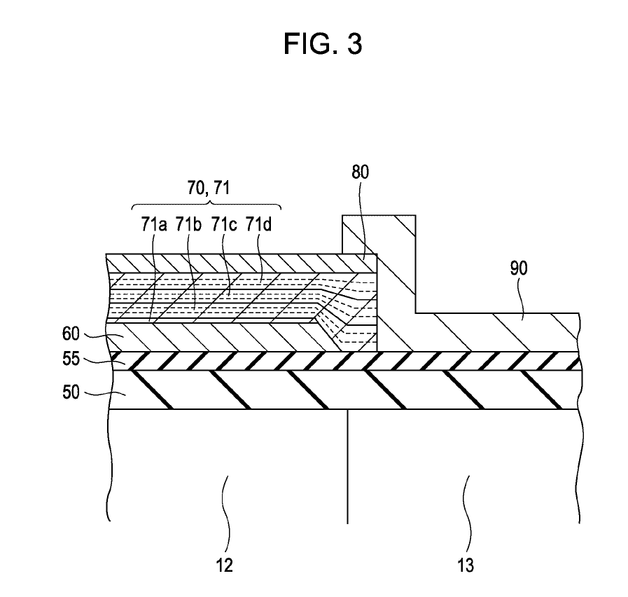

FIG. 1 is an exploded perspective diagram illustrating an ink jet recording head according Embodiment 1. FIG. 2A illustrates a plan view of FIG. 1, and FIG. 2B illustrates a cross section taken along line IIB-IIB. FIG. 3 is a cross-sectional diagram illustrating the laminar structure of a piezoelectric element.

As illustrated in the drawings, a flow channel substrate 10, a first substrate, has either one of its sides covered with an elastic film 50. The flow channel substrate 10 is a silicon substrate, and the elastic film 50 is an oxide film. On the flow channel substrate 10, several pressure chambers 12, which are defined by partitions 11, are arranged in parallel in the width direction thereof. One of the two volumes expanding along the longitudinal ends of the pressure chambers 12 has ink supply paths 13 and communicating paths 14. The ink supply paths 13 and the communicating paths 14 are defined by the partitions 11 and arranged in series next to the individual pressure chambers 12. There is also a communicating space 15, which is so formed as to communicate with the communicating paths 14 from outside. Communicating with the reservoir space 32 of a protective substrate 30, the communicating space 15 serves as a component of a reservoir 100, a common ink tank for the pressure chambers 12. The protective substrate 30 is a second substrate; it will be described later.

The other side of the flow channel substrate 10 is bonded to a nozzle plate 20 with an adhesive agent or the like. This nozzle plate 20 is made of a glass ceramic, a silicon single crystal, stainless steel, or some other appropriate material. The nozzle plate 20 has nozzles 21, and the nozzles 21 are so formed as to communicate with the pressure chambers 12.

As described above, the flow channel substrate 10 has either one of its sides covered with the elastic film 50. This elastic film 50 is covered with an insulating film 55, and this insulating film 55 is made of a material different from that of the elastic film 50. The insulating film 55 has piezoelectric elements 300 arranged thereon, and these piezoelectric elements 300 each serve as pressure generators for the pressure chambers 12. In this embodiment, each piezoelectric element 300 is constituted by a lower electrode film (a first electrode film) 60, a piezoelectric layer 70, and an upper electrode film (a second electrode film) 80. The lower electrode film 60 provides a common electrode for the piezoelectric elements 300, and the upper electrode film 80 provides separate electrodes for the piezoelectric elements 300.

The lower electrode film 60 is cut near both longitudinal ends of the pressure chambers 12 so as to fit the pressure chambers 12 as a whole and extend in the direction of their arrangement. The portions of the lower electrode film 60 facing the pressure chambers 12 have slopes at both longitudinal ends, or in other words, both end faces of these portions are at a certain angle to the surface of the insulating film 55.

The piezoelectric layer 70 has separate blocks corresponding to the pressure chambers 12. An exemplary constitution of each block of the piezoelectric layer 70 is a laminate of several ferroelectric films 71 (71a to 71d), as illustrated in FIG. 3. These ferroelectric films 71 are made of lead zirconate titanate (PZT) or some other appropriate ferroelectric material. The lowermost one of the ferroelectric films 71, namely, the first ferroelectric film 71a, is so formed as to cover the lower electrode film 60 only and has slopes at both longitudinal ends. These slopes are so formed as to make a continuous surface with the slopes of the lower electrode film 60. The remaining ones of the ferroelectric films 71, namely, the second to fourth ferroelectric films 71b to 71d, are so formed as to cover the whole surface from the first ferroelectric film 71a to the insulating film 55, including the slopes of the first ferroelectric film 71a and those of the lower electrode film 60.

As with the piezoelectric layer 70, the upper electrode film 80 also has separate blocks corresponding to the pressure chambers 12. These blocks of the upper electrode film 80 are connected via lead electrodes 90 to a driving IC. This driving IC will be described later.

The side of the flow channel substrate 10 having the piezoelectric elements 300 arranged thereon, or in other words, the side on which the lower electrode film 60, insulating film 55, and lead electrodes 90 are exposed, is covered with a protective substrate 30 bonded thereto via an adhesive agent 35 or some other appropriate agent. This protective substrate 30 is a second substrate as mentioned above, and it has, besides the reservoir space 32, a piezoelectric element housing 31 for protecting the piezoelectric elements 300. As described above, the reservoir space 32 communicates with the communicating space 15 to provide a reservoir 100. The protective substrate 30 further has a through hole 33 penetrating its entire thickness. The individual lead electrodes 90, extending from their corresponding piezoelectric elements 300, have a portion exposed in the through hole 33 near one of the ends thereof.

The material of the protective substrate 30 is preferably, but not limited to, one having a coefficient of thermal expansion almost equal to that of the flow channel substrate 10, for example, a glass material, a ceramic material, or the like. In this embodiment, the protective substrate 30 is a silicon substrate as with the flow channel substrate 10.

The protective substrate 30 further has a compliance substrate 40 bonded thereto, and this compliance substrate 40 consists of a sealing film 41 and a stationary plate 42. The sealing film 41 is made of a flexible material with a low rigidity and seals one of the openings of the reservoir space 32, whereas the stationary plate 42 is made of a harder material such as metal and has an opening 43 penetrating its entire thickness over the area corresponding to the reservoir 100. As a result, one of the openings of the reservoir 100 is sealed only with the sealing film 41, a flexible film.

An ink jet recording head according to this embodiment receives ink from an external ink source (not illustrated in the drawings), fills the entire space from the reservoir 100 to the nozzles 21 with ink, and then, in response to recording signals transmitted from a driving IC, applies voltage to appropriate ones of the piezoelectric elements 300 so that they should be deformed to bend; as a result, the pressure chambers 12 corresponding to the deformed ones of the piezoelectric elements 300 are pressurized to eject ink droplets through the nozzles 21.

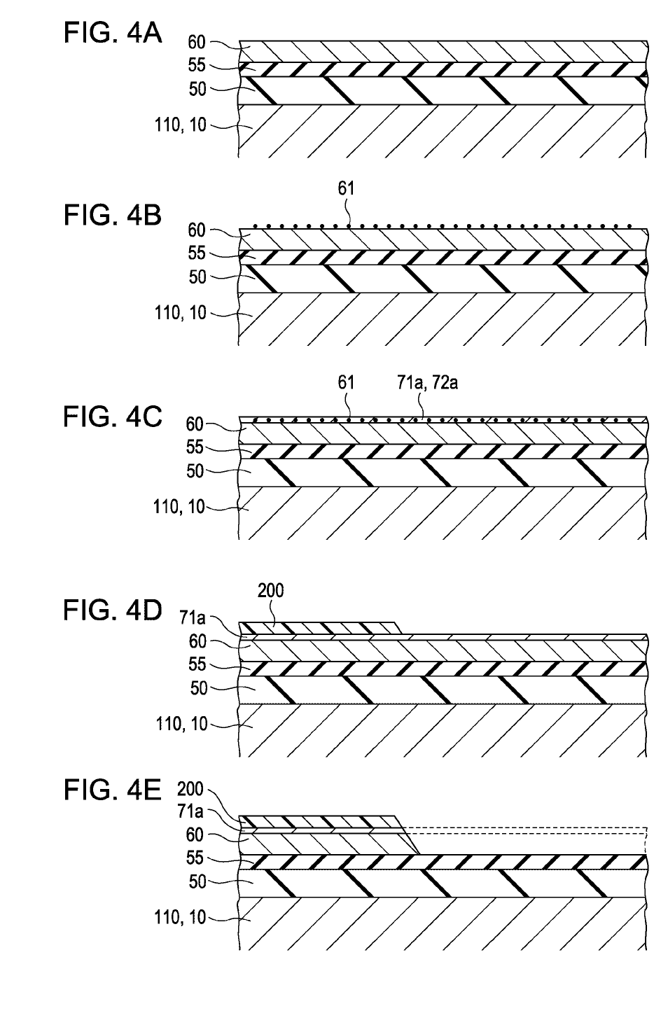

The following describes a method for manufacturing an ink jet recording head like the one described above with reference to FIGS. 4A to 9C, with a method for fabricating piezoelectric elements especially detailed.

First, as illustrated in FIG. 4A, an elastic film 50 and an insulating film 55 are formed in this order on a flow channel substrate wafer (or an element substrate wafer) 110. Then, a lower electrode film 60 is formed on the insulating film 55. The flow channel substrate wafer 110 is a wafer made of silicon or some other appropriate material, and the central portion thereof is used to produce several flow channel substrates (several element substrates) as a whole. The method used to form these films is not particularly limited.

Then, a piezoelectric layer 70 is formed on the lower electrode film 60. As described above, this piezoelectric layer 70 is a laminate of ferroelectric films 71 (71a to 71d). In this embodiment, these ferroelectric films 71 are individually formed by the sol-gel method as follows: A metal organic compound is dissolved or dispersed in a solvent, the resultant sol is applied and dried to provide a ferroelectric precursor film 72 in the form of gel, and the resultant gel is defatted to be free from organic substances and then fired until it crystallizes.

Specific processes for forming the ferroelectric films 71 are as follows. First, as illustrated in FIG. 4B, a layer of seed crystals 61 of titanium or titanium oxide is formed on the lower electrode film 60 by sputtering. Then, as illustrated in FIG. 4C, a ferroelectric precursor film 72a is formed to a certain thickness, for example, about 110 nm, by spin coating or some other appropriate coating technique. Note that in this process, the ferroelectric precursor film 72a is in its amorphous state. Then, the ferroelectric precursor film 72a is dried at a certain temperature for a certain period of time until the solvent is evaporated. The drying temperature is preferably in the range of 150 to 200° C. and more preferably about 180° C., but not limited to these. The drying time is preferably in the range of 5 to 15 minutes and more preferably about 10 minutes, but not limited to these. Then, the ferroelectric precursor film 72a dried is defatted at a certain temperature. The term degreasing used here represents removing organic substances from the ferroelectric precursor film 72a by converting them into NO₂, CO₂, H₂O, or other species. In this degreasing process, the temperature for the heating of the flow channel substrate wafer 110 is preferably on the order of 300 to 500° C. Too high a heating temperature may allow the ferroelectric precursor film 72a to crystallize, and too low a heating temperature may lead to incomplete degreasing.

After the ferroelectric precursor film 72a is defatted in the way described above, the flow channel substrate 110 is processed in a rapid thermal annealing (RTA) system or some other appropriate apparatus so that the ferroelectric precursor film 72a should be fired at a high temperature, for example, at about 700° C., until it crystallizes. In this way, a first ferroelectric film 71a, namely, the lowermost one of the ferroelectric films 71, is obtained.

Then, the first ferroelectric film 71a and the lower electrode film 60 are patterned together. First, as illustrated in FIG. 4D, a resist is applied to the first ferroelectric film 71a and then exposed to light and developed to provide a resist film 200 having the intended pattern. The resist is preferably a negative resist; however, a positive resist may be used instead.

Then, as illustrated in FIG. 4E, the first ferroelectric film 71a and the lower electrode film 60 are patterned by ion milling or some other appropriate dry-etching technique with the resist film 200 as the mask. After being patterned, the first ferroelectric film 71a and the lower electrode film 60 have slopes. These slopes are so formed as to make a continuous surface with the slopes of the resist film 200.

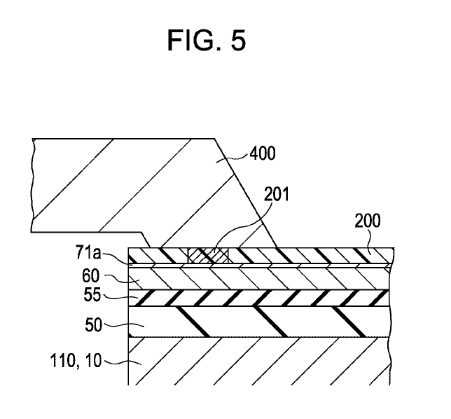

Incidentally, this dry-etching process usually requires the flow channel substrate wafer 110 to be held with a holding member 400, such as a metal ring chuck, on its edge, as illustrated in FIG. 5. In some cases, the heat transferred from the holding member 400 hardens portions of the resist film 200, forming hard flakes 201. Hard flakes 201 are less removable than the remaining portion of the resist film 200. Thus, attempts to completely remove the hard flakes 201 may lead to damage to the surface of the first ferroelectric film 71a.

To address this problem, more specifically, for reduced damage to the surface of the first ferroelectric film 71a, the resist film 200 and its hardened portions, hard flakes 201, are removed in the following way.

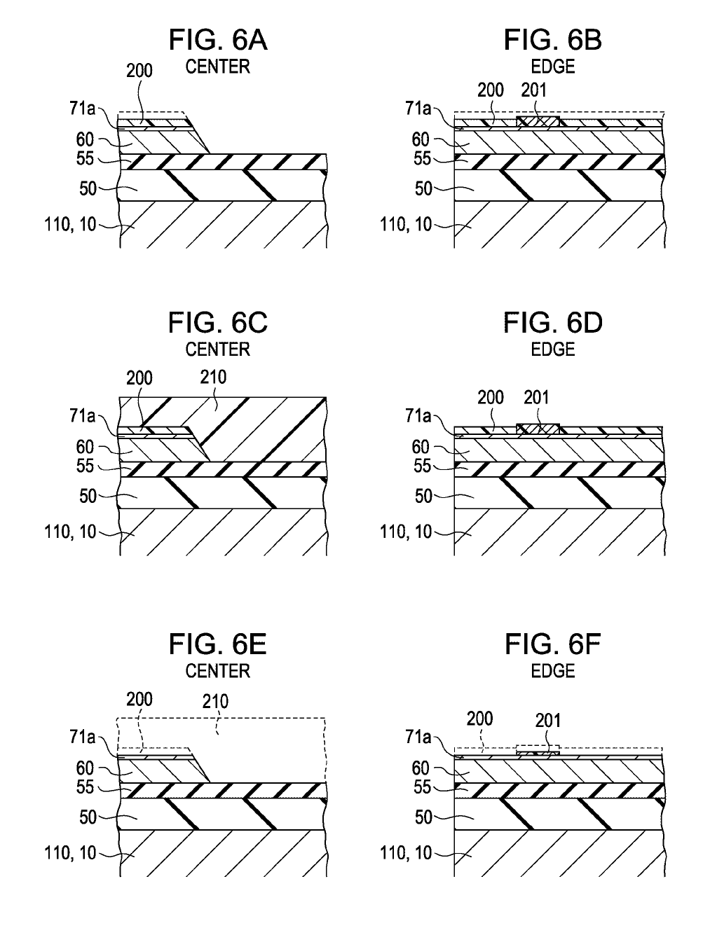

First, as illustrated in FIGS. 6A and 6B, the resist film 200 lying on the first ferroelectric film 71a is removed in its thickness direction to some extent, for example, by about half the thickness, by asking with oxygen plasma (the first resist removal step). At the edge of the flow channel substrate wafer 110, the hard flakes 201 of the resist film 200 are removed to a less extent than the remaining portion; as a result, the hard flakes 201 have a greater thickness than the remaining portion. Then, as illustrated in FIG. 6C, a protective resist film 210 is formed to cover at least the first ferroelectric film 71a. In this embodiment, this protective resist film 210 is so formed as to cover the central portion of the flow channel substrate wafer 110 (or the chip region, a region to be diced into flow channel substrates 10). In other words, the edge of the flow channel substrate wafer 110 (the region excluding the chip region) is exposed as illustrated in FIG. 6D.

Then, ashing with oxygen plasma is performed once again to remove the protective resist film 210 and the first resist film 200 as illustrated in FIGS. 6E and 6F (the second resist removal step). This ashing process should be terminated before the surface of the first ferroelectric film 71a is damaged. This process thus can remove the hard flakes 201 to a great extent but cannot completely remove them.

The remaining pieces of the hard flakes 201 are later peeled off by treatment with an organic remover or some other appropriate agent (the third resist removal step). In this third resist removal step, the surface of the first ferroelectric film 71a is still at risk of being damaged because of the direct contact with the remover. However, the hard flakes 201 have been removed to a great extent as a result of asking with oxygen plasma repeated several times, and thus the time needed to finish peeling off the hard flakes 201 with the remover is not so long, and the damage to the surface of the first ferroelectric film 71a is almost entirely avoided. This way of peeling off the resist film 200 is advantageous in that it allows effectively removing the resist film 200 and its hardened portions, hard flakes 201, while avoiding damage to the surface of the first ferroelectric film 71a.

As a result, the second to fourth ferroelectric films 71b to 71d, which are formed on the first ferroelectric film 71a in the process described below, take over crystallographic properties from the first ferroelectric film 71a, and the resultant piezoelectric layer 70 has excellent crystallographic properties.

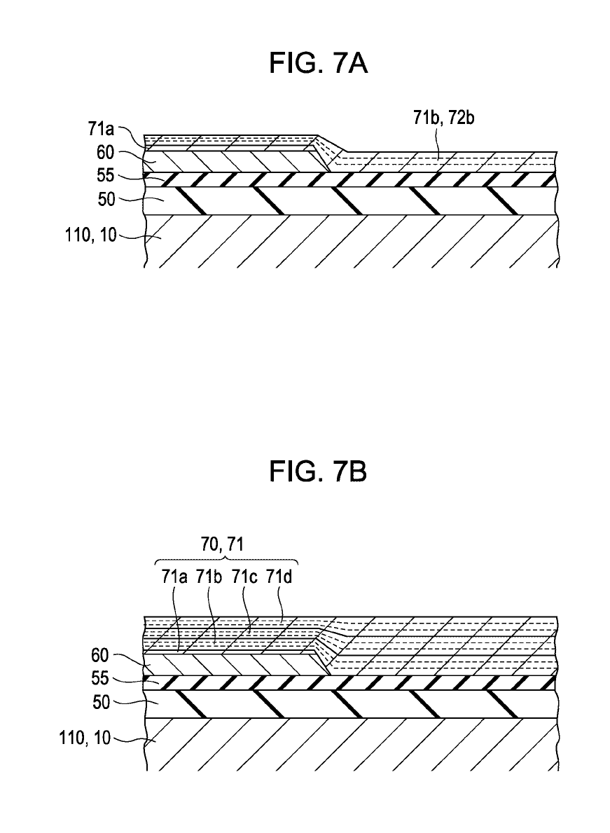

Specific processes for forming the second to fourth ferroelectric films 71b to 71d are as follows. First, as illustrated in FIG. 7A, a ferroelectric precursor film 72b is formed on the first ferroelectric film 71a by spin coating or some other appropriate coating technique to any thickness with which the second ferroelectric film 71b left after firing is about 330 nm in thickness. In this embodiment, such a thickness is obtained by layering three ferroelectric films, namely, the second to fourth ferroelectric films 71b to 71d. Then, the ferroelectric precursor film 72b is dried, defatted, and then fired until it crystallizes to give the second ferroelectric film 71b. Additional ferroelectric films can be obtained by repeating the same cycle as many times as needed; the resultant laminate of ferroelectric films is the piezoelectric layer 70. In this embodiment, the second to fourth ferroelectric films 71b to 71d are formed as illustrated in FIG. 7B by repeating the cycle described above three times; the resultant piezoelectric layer 70, which is a laminate of four ferroelectric films, namely, the first to fourth ferroelectric films 71a to 71d, has a thickness of about 1 μm.

As described above, this embodiment employs three resist removal steps: the first one for removing the resist film 200, which is a mask for the patterning of the first ferroelectric film 71a, by performing asking with oxygen plasma several times (e.g., twice), the second one for removing the hard flakes 201, hardened portions of the resist film 200, and the third one by treatment with an organic remover or some other appropriate agent. As a result, the piezoelectric layer 70 has excellent crystallographic properties. More specifically, crystallites packed in the first to fourth ferroelectric films 71a to 71d to constitute the piezoelectric layer 70 form pillars extending through the substantially full thickness of the piezoelectric layer 70, from the first ferroelectric film 71a to the fourth ferroelectric film 71d. Furthermore, these crystallites have a preferred orientation along the (100) plane. This gives improved displacement properties to the piezoelectric elements 300, and thus the resultant liquid ejecting head offers excellent performance in ink ejection. Here, the expression crystallites have a preferred orientation means that their orientations are not random and the majority of them share the same direction of orientation on one of their own crystallographic planes. Also, the term pillar, which is used above to refer to the crystallites constituting the ferroelectric films 71a to 71d, represents approximately cylindrical crystallites piled up with their central axes in a substantially straight line; closely packed and arranged in parallel, pillars constitute the ferroelectric films 71a to 71d.

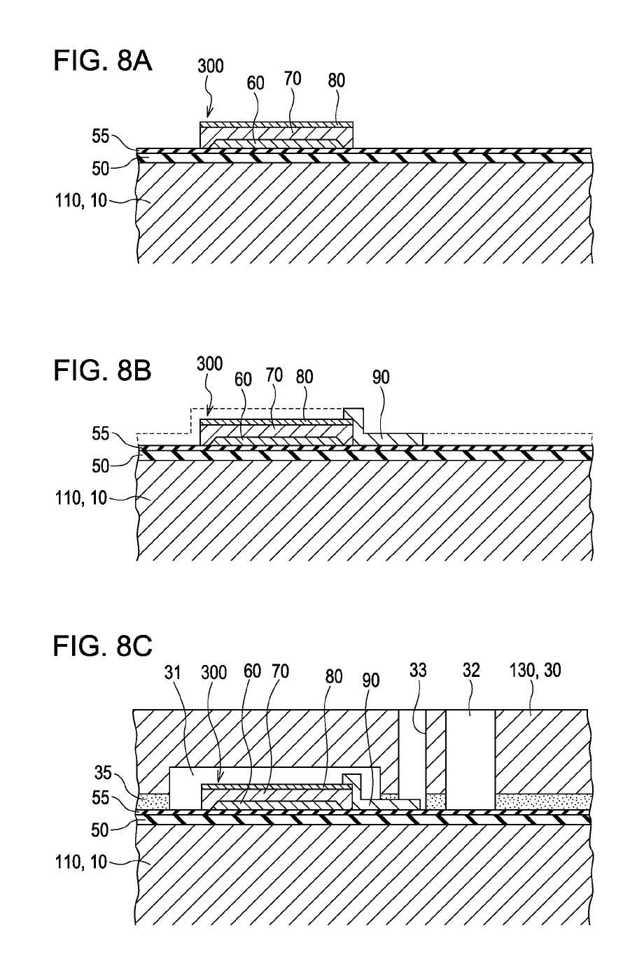

After the piezoelectric layer 70 is completed with the ferroelectric films 71a to 71d, an upper electrode film 80 is formed on the piezoelectric layer 70, and then the upper electrode film 80 and the piezoelectric layer 70 are patterned into blocks that fit the pressure chambers 12. As a result, the piezoelectric elements 300 are completed to fit the pressure chambers 12 as illustrated in FIG. 8A.

After that, as illustrated in FIG. 8B, a metal layer is formed from gold (Au) or some other appropriate metal to cover the whole surface of the flow channel substrate wafer 110. Then, this metal layer is patterned into blocks that fit the piezoelectric elements 300 with a resist pattern or the like as the mask (not illustrated in the drawing). As a result, the lead electrodes 90 are formed. Then, as illustrated in FIG. 8C, a protective substrate wafer 130, a wafer having a portion to be divided into several protective substrates 30, is bonded to the flow channel substrate wafer 110 with the adhesive agent 35. Note that the protective substrate wafer 130 used here has units each consisting of the piezoelectric element housing 31, reservoir space 32, and other necessary components formed thereon in advance.

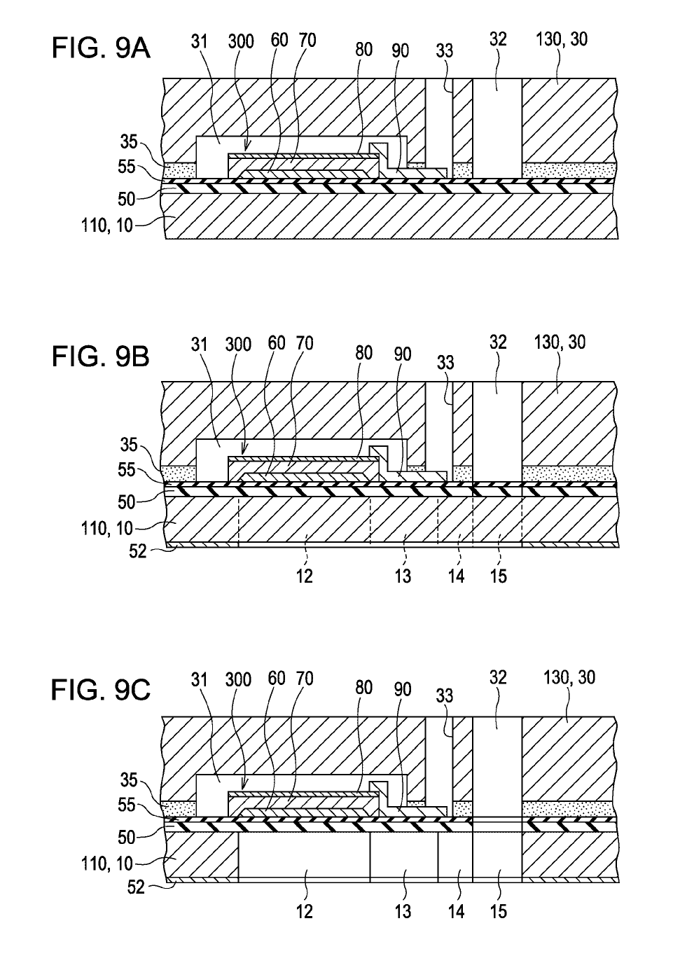

Subsequently, the flow channel substrate wafer 110 is polished to some extent and then subjected to wet etching with hydrofluoric-nitric acid to have a certain thickness as illustrated in FIG. 9A. Then, as illustrated in FIG. 9B, a protective film 52 is formed on the flow channel substrate wafer 110 from silicon nitride (SiN) or some other appropriate compound and shaped into a certain pattern. Then, as illustrated in FIG. 9C, the flow channel substrate wafer 110 is subjected to anisotropic (wet) etching with this protective film 52 as the mask. As a result, the pressure chambers 12 and other necessary flow channels are formed on the flow channel substrate wafer 110.

After that, the edge of the flow channel substrate wafer 110 and protective substrate wafer 130 is cut by dicing or some other appropriate technique so that all unnecessary portion should be removed therefrom. Then, a nozzle plate 20, which is drilled in advance to have nozzles 21, is bonded to the side of the flow channel substrate wafer 110 opposite to that to which the protective substrate wafer 130 is bonded, and a compliance substrate 40 is bonded to the protective substrate wafer 130. Finally, the structure obtained is divided into chips each incorporating the flow channel substrate 10 and all other necessary components. In this way, an ink jet recording head having the constitution described above is obtained.

### Embodiment 2

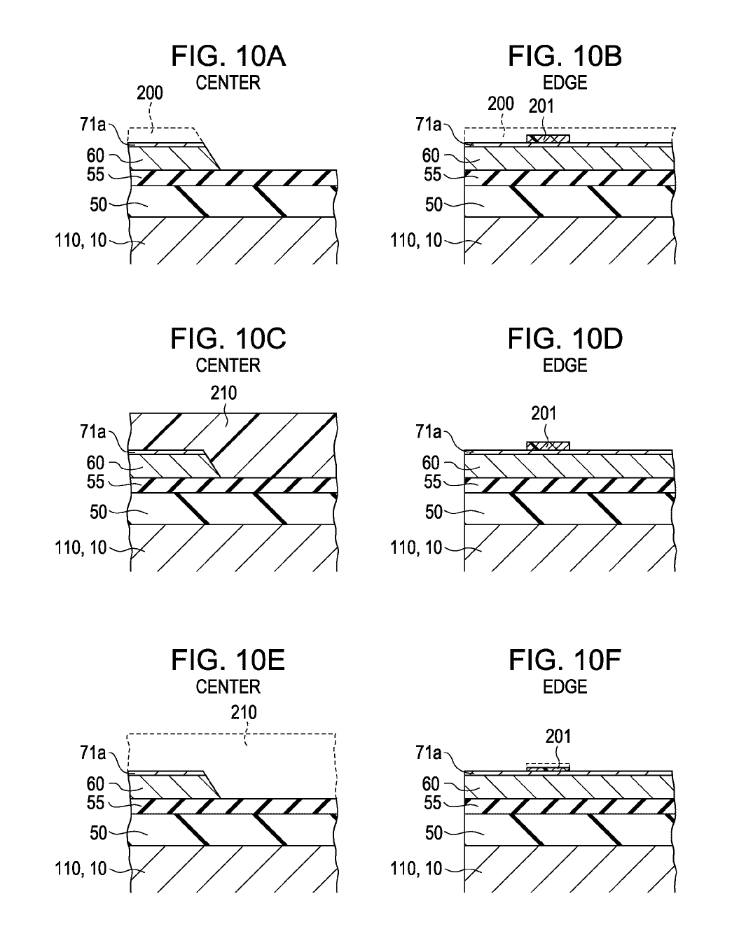

FIGS. 10A to 10F are cross-sectional diagrams illustrating a method for manufacturing an ink jet recording head according to Embodiment 2. This embodiment provides another exemplary method for manufacturing an ink jet recording head (and that for fabricating piezoelectric elements), in which the steps for removing the resist film 200 are different from those in Embodiment 1.

The resist removal steps according to Embodiment 2 are as follows. After the first ferroelectric film 71a and the lower electrode film 60 are patterned with the resist film 200 as the mask, the resist film 200 lying on the first ferroelectric film 71a is completely removed by ashing with oxygen plasma as illustrated in FIGS. 10A and 10B (the first resist removal step). This ashing process should be terminated before the surface of the first ferroelectric film 71a is damaged. Thus, the hard flakes 201 are not completely removed from the edge of the flow channel substrate wafer 110.

Then, a protective resist film 210 is formed in such a manner that the central portion, or the chip region, of the flow channel substrate wafer 110 should be covered as illustrated in FIGS. 10C and 10D. After that, ashing with oxygen plasma is performed once again to remove the protective resist film 210 as illustrated in FIGS. 10E and 10F (the first resist removal step). This ashing process should also be terminated before the surface of the first ferroelectric film 71a is damaged; the hard flakes 201 are removed to a great extent, but not completely removed from the edge of the flow channel substrate wafer 110.

The next process is the same as in Embodiment 1; the flow channel substrate wafer 110 is treated with an organic remover or some other appropriate agent (the second half of the second resist removal step). In this way, the hard flakes 201 can be effectively peeled off of the edge of the flow channel substrate 110.

This way of peeling off the resist film 200 also allows effectively removing the resist film 200 and its hardened portions, hard flakes 201, while avoiding damage to the surface of the first ferroelectric film 71a. As a result, the second to fourth ferroelectric films 71b to 71d take over crystallographic properties from the first ferroelectric film 71a, and the resultant piezoelectric layer 70 has excellent crystallographic properties.

### Embodiment 3

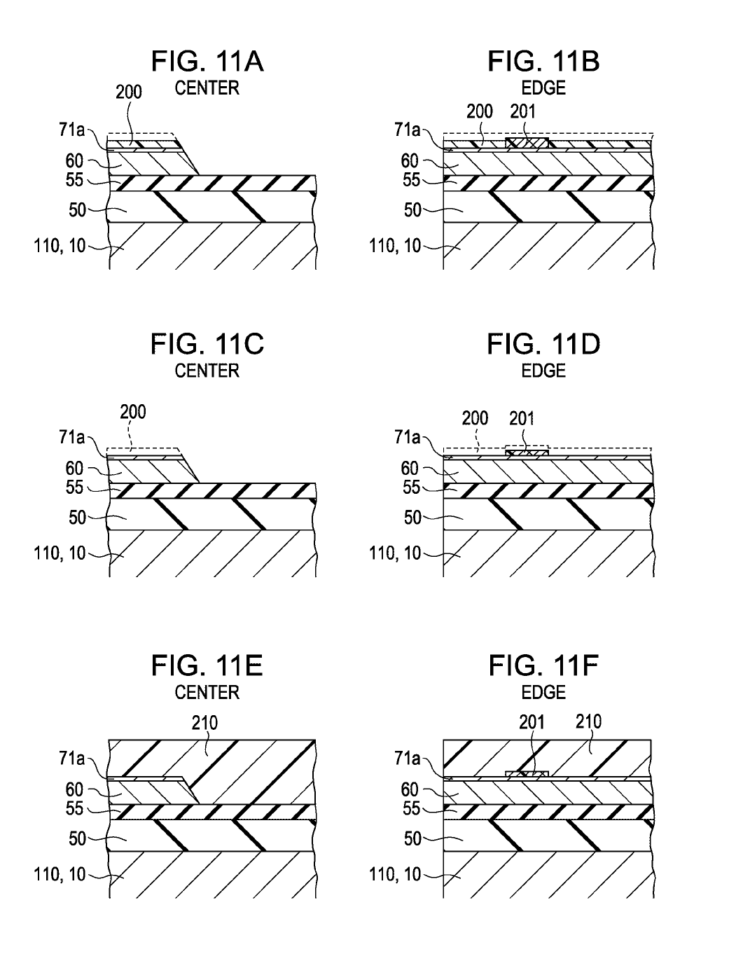

FIGS. 11A to 11F are cross-sectional diagrams illustrating a method for manufacturing an ink jet recording head according to Embodiment 3. This embodiment provides yet another exemplary method for manufacturing an ink jet recording head (and that for fabricating piezoelectric elements), in which the steps for removing the resist film 200 are different from those in Embodiments 1 and 2.

The resist removal steps according to Embodiment 3 are as follows. After the first ferroelectric film 71a and the lower electrode film 60 are patterned with the resist film 200 as the mask, the resist film 200 lying on the first ferroelectric film 71a is removed in its thickness direction to some extent, for example, by about half the thickness, by asking with oxygen plasma as illustrated in FIGS. 11A and 11B (the first resist removal step). At the edge of the flow channel substrate wafer 110, the hard flakes 201 of the resist film 200 removed to a less extent than the remaining portion; as a result, the hard flakes 201 have a greater thickness than the remaining portion.

Then, as illustrated in FIG. 11C, the portion of the resist film 200 left on the first ferroelectric film 71a is removed by treatment with an organic remover or some other appropriate agent (the second resist removal step). This treatment process may involve the exposure of the surface of the first ferroelectric film 71a to the remover and thus should be terminated before the damage to the surface of the first ferroelectric film 71a is serious. This process thus can remove the hard flakes 201 to a great extent but cannot completely remove them from the edge of the flow channel substrate wafer 110, as illustrated in FIG. 11D. However, the hard flakes 201 become easier to peel off owing to the action of the remover.

Then, a protective resist film 210 is formed, in such a manner that the central portion, or the chip region, of the flow channel substrate wafer 110 should be covered as illustrated in FIGS. 11E and 11F. After that, the flow channel substrate wafer 110 is treated with the remover once again to remove the protective resist film 210 (the third resist removal step). This process removes the hard flakes 201 from the edge of the flow channel substrate wafer 110 together with the protective resist film 210.

This way of removing the resist film 200 also allows effectively removing the resist film 200 and its hardened portions, hard flakes 201, while avoiding damage to the surface of the first ferroelectric film 71a. As a result, the second to fourth ferroelectric films 71b to 71d take over crystallographic properties from the first ferroelectric film 71a, and the resultant piezoelectric layer 70 has excellent crystallographic properties.

### Other Embodiments

The constitution of this aspect of the invention is not limited to the embodiments described above. For example, the simultaneous removal of the resist film and its hardened portions from the edge of the flow channel substrate wafer can also be applied even if ion milling etches some portions of the holding member used therewith and the resultant contaminants (depositions) adhere to the resist film. Overall, manufacturing methods according to this aspect of the invention all allow effectively removing the resist film while avoiding damage to the surface of the first ferroelectric film whether the resist film has hardened portions or retains contaminants adhering thereto.

Although the embodiments described above deal with ink jet recording heads as a typical liquid ejecting head, this aspect of the invention covers other various kinds of liquid ejecting heads and the full range of liquid ejecting apparatus. Examples of liquid ejecting heads to which this aspect of the invention can be applied include recording heads for printers and other kinds of image recording apparatus, colorant ejecting heads for manufacturing color filters for liquid crystal displays and other kinds of displays, electrode material ejecting heads for forming electrodes for organic EL displays, field emission displays (FEDs), and other kinds of displays, bioorganic substance ejecting heads for manufacturing biochips, and so forth. Of course, not only do piezoelectric elements for liquid ejecting heads but also those for other devices may benefit from the manufacturing methods according to this aspect of the invention, for example, those for microphones, sounding bodies, vibrators, oscillators, and so forth.

What is claimed is:

1. A method for manufacturing a liquid ejecting head containing a plurality of flow channel substrates and a plurality of piezoelectric elements, the flow channel substrates each having a pressure chamber communicating with a nozzle for ejecting a droplet and the piezoelectric elements each constituted by a first electrode film formed on either one side of each of the flow channel substrates, a piezoelectric layer constituted by a plurality of ferroelectric films and formed on the first electrode film, and a second electrode film formed on the first electrode film, comprising:
forming the first electrode film on a flow channel substrate wafer, a wafer having a portion to be divided into the flow channel substrates;
forming a first ferroelectric film, or the lowermost one of the ferroelectric films constituting the piezoelectric layer, by forming a ferroelectric precursor film on the first electrode film to a certain thickness and then degreasing and firing the ferroelectric precursor film;
shaping the first ferroelectric film and the first electrode film into a certain pattern by applying a resist to the first ferroelectric film, exposing the resist to light and developing it so that a resist film can be obtained with the pattern, and then etching the first ferroelectric film and the first electrode film with this resist film as the mask;
removing the resist film to some extent in the thickness direction by asking with oxygen plasma;
forming a protective resist film to cover the first ferroelectric film by applying a resist to the central portion of the flow channel substrate wafer;
removing the resist film and the protective resist film by treatment with an organic remover with or without any pretreatment;
forming the remaining ones of the ferroelectric films constituting the piezoelectric layer by forming a ferroelectric precursor film on the first ferroelectric film to a certain thickness and then degreasing and firing the ferroelectric precursor film and then repeating the same cycle as many times as needed; and
completing the piezoelectric elements by forming the second electrode film on the piezoelectric layer and then shaping the second electrode film and the ferroelectric films other than the first ferroelectric film into a certain pattern.

2. The method for manufacturing a liquid ejecting head according to claim 1, wherein:
the protective resist film is so formed as to cover the chip region of the flow channel substrate wafer, or in other words, the entire portion to be divided into the flow channel substrates.

3. The method for manufacturing a liquid ejecting head according to claim 1, further comprising:
removing the first resist film and the protective film by ashing with oxygen plasma in preparation for removing the resist film and the protective resist film by treatment with an organic remover.

4. The method for manufacturing a liquid ejecting head according to claim 1, further comprising:
removing, by treatment with an organic remover, the portion of the resist film left after removing the resist film to some extent in the thickness direction by ashing with oxygen plasma.

5. A method for fabricating a plurality of piezoelectric elements, the piezoelectric elements each constituted by a first electrode film formed on either one side of each of a plurality of element substrates, a piezoelectric layer constituted by a plurality of ferroelectric films and formed on the first electrode film, and a second electrode film formed on the first electrode film, comprising:
forming the first electrode film on a element substrate wafer, a wafer having a portion to be divided into the element substrates;
forming a first ferroelectric film, or the lowermost one of the ferroelectric films constituting the piezoelectric layer, by forming a ferroelectric precursor film on the first electrode film to a certain thickness and then degreasing and firing the ferroelectric precursor film;
shaping the first ferroelectric film and the first electrode film into a certain pattern by applying a resist to the first ferroelectric film, exposing the resist to light and developing it so that a resist film can be obtained with the pattern, and then etching the first ferroelectric film and the first electrode film with this resist film as the mask;
removing the resist film to some extent in the thickness direction by asking with oxygen plasma;
forming a protective resist film to cover the first ferroelectric film by applying a resist to the central portion of the element substrate wafer;
removing the resist film and the protective resist film by treatment with an organic remover with or without any pretreatment;
forming the remaining ones of the ferroelectric films constituting the piezoelectric layer by forming a ferroelectric precursor film on the first ferroelectric film to a certain thickness and then degreasing and firing the ferroelectric precursor film and then repeating the same cycle as many times as needed; and
completing the piezoelectric elements by forming the second electrode film on the piezoelectric layer and then shaping the second electrode film and the ferroelectric films other than the first ferroelectric film into a certain pattern.
